(19) United States
(12) Patent Application Publication
(10) Pub. No.: US 2015/0000597 A1
(43) Pub. Date: Jan. 1, 2015

(54) REDUCED ZINC SHOWERHEAD

(71) Applicant: Applied Materials, Inc., Santa Clara, CA (US)

(72) Inventors: Nishil NAMBIAR, Los Gatos, CA (US); Kinya AMADA, Chiba (JP)

(73) Assignee: Applied Materials, Inc., Santa Clara, CA (US)

(21) Appl. No.: 14/038,578

(22) Filed: Sep. 26, 2013

Related U.S. Application Data
(60) Provisional application No. 61/841,484, filed on Jul. 1, 2013.

(51) Int. Cl. C23C 16/455

(52) U.S. Cl. CPC C23C 16/45565
USPC 118/723 R; 420/528; 420/540; 239/548

(57) ABSTRACT

Embodiments described herein generally relate to an aluminum alloy showerhead with a reduced zinc content for use in semiconductor processing chambers. The showerhead may be utilized in processing chambers adapted for making low temperature polysilicon (LTPS) liquid crystal displays (LCD) or LTPS organic light emitting diode (OLED) displays which may be controlled by thin film transistors (TFT). More specifically, embodiments described herein relate to a reduced zinc showerhead.

### CROSS-REFERENCE TO RELATED APPLICATIONS

This application claims benefit of U.S. provisional patent application Ser. No. 61/841,484, filed Jul. 1, 2013, which is herein incorporated by reference.

### BACKGROUND OF THE INVENTION

1. Field of the Invention

Embodiments described herein generally relate to an aluminum alloy showerhead with a reduced zinc content for use in processing chambers. The showerhead may be utilized in processing chambers adapted for making low temperature polysilicon (LTPS) liquid crystal displays (LCD) or LTPS organic light emitting diode (OLED) displays which may be controlled by thin film transistors (TFTs). More specifically, embodiments described herein relate to a reduced zinc showerhead.

2. Description of the Related Art

Current interest in TFT arrays is particularly high because these devices may be used in LCDs of the kind often employed for computer and television flat panels. The LCDs may also contain light emitting diodes (LEDs), such as OLEDs for back lighting. The LEDs and OLEDs require TFTs for addressing the activity of the displays.

LTPS displays generally require processing at elevated temperatures in order to deposit the polysilicon. A common source of particle creation during processing is copper metal contamination due to the migration of copper in devices. However, other sources of particle contamination may exist during processing. Particles present during processing may degrade TFT device performance.

Thus, what is needed in the art are apparatuses for reducing particle contamination during TFT device manufacturing.

### SUMMARY OF THE INVENTION

Embodiments described herein generally relate to an aluminum showerhead, or diffuser, with a reduced zinc content for use in semiconductor processing chambers. LTPS based LCDs or LTPS based OLEDs are generally controlled by TFTs. Particle contamination in the processing chamber during fabrication of the TFTs may reduce the performance capability and reliability of the TFTs. The reduced zinc showerhead may reduce the presence of zinc particles within the processing chamber and improve TFT device performance.

In one embodiment, a diffuser for processing semiconductor substrates is provided. The diffuser may comprise a body comprising an aluminum alloy, wherein the aluminum alloy comprises less than or equal to 0.01 wt % of zinc.

In another embodiment, a diffuser for use in a plasma enhanced chemical vapor deposition chamber is provided. The diffuser may comprise a body comprising an aluminum alloy containing less than or equal to 0.01 wt % of zinc, wherein the diffuser may be adapted for operation in an environment having a temperature above 400° C.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional schematic view of a PECVD chamber according to certain embodiments described herein;

FIGS. 2A-2C are schematic cross-sectional views of a TFT at various stages of production according to certain embodiments described herein; and

FIG. 3 is a cross-sectional schematic diagram of a TFT controlling an LCD pixel or OLED according to certain embodiments described herein.

FIG. 4 is a color photograph of a portion of a backing plate having a zinc material deposited thereon.

FIG. 5 is a color photograph of a portion of a backing plate having substantially no zinc material deposited thereon.

FIG. 6 is a graph illustrating elemental analysis of a portion of a chamber having a zinc material deposited thereon.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to an aluminum showerhead, or diffuser, with a reduced zinc content for use in semiconductor processing chambers. LTPS based LCDs or LTPS based OLEDs are generally controlled by TFTs. Particle contamination in the processing chamber during fabrication of the TFTs may reduce the performance capability and reliability of the TFTs. The reduced zinc showerhead may reduce the presence of zinc particles within the processing chamber and improve TFT device performance.

The invention is illustratively described below utilized in a processing system, such as a plasma enhanced chemical vapor deposition (PECVD) system available from AKT America, a division of Applied Materials, Inc., located in Santa Clara, Calif. However, it should be understood that the invention has utility in other system configurations, including those sold by other manufacturers.

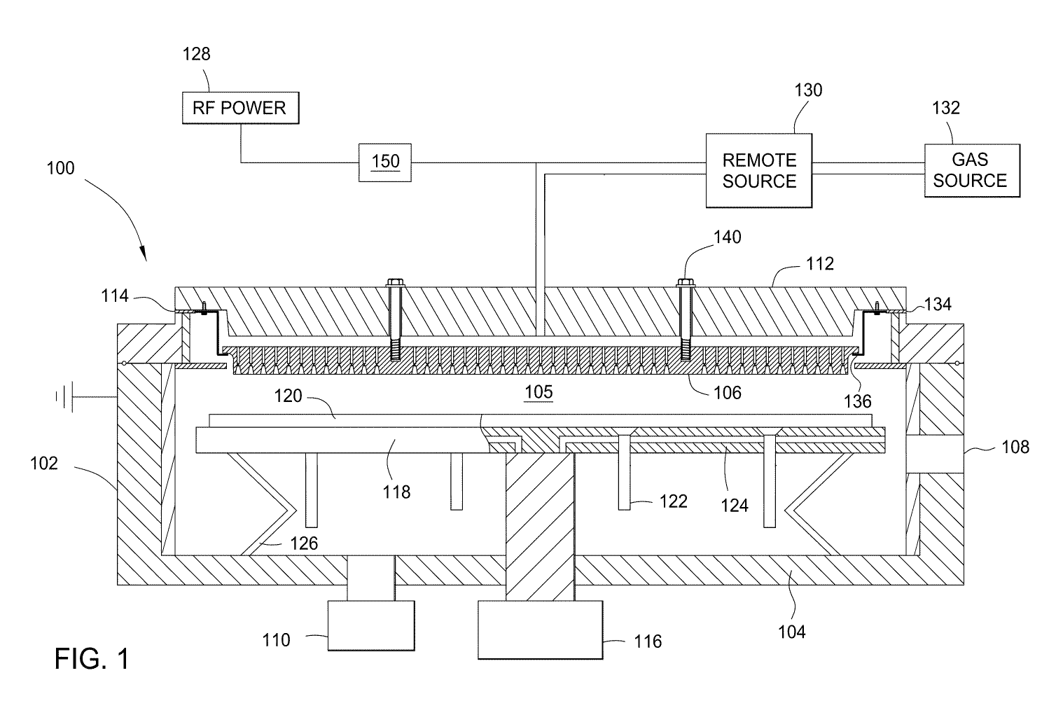

FIG. 1 is a schematic, cross sectional view of an apparatus that may be used to perform the operations described herein. The apparatus includes a chamber 100 in which one or more films may be deposited onto a substrate 120. The chamber 100 generally includes walls 102, a bottom 104 and a showerhead 106 which define a process volume 105. A substrate support 118 may be disposed within the process volume 105. The process volume 105 is accessed through a slit valve opening 108 such that the substrate 120 may be transferred in and out of the chamber 100. The substrate support 118 may be coupled to an actuator 116 to raise and lower the substrate support 118. Lift pins 122 are moveably disposed through the substrate support 118 to move a substrate to and from a substrate receiving surface. The substrate support 118 may also include heating and/or cooling elements 124 adapted to maintain the substrate support 118 at a desired temperature. The substrate support 118 can also include RF return straps 126 to provide an RF return path at the periphery of the substrate support 118.

The showerhead 106 may be coupled to a backing plate 112 by one or more fastening mechanisms 140. The one or more fastening mechanisms 140 may help prevent sag and/or control the straightness/curvature of the showerhead 106. The showerhead 106 may be formed from a metal such as aluminum, stainless steel, and alloys thereof. In one embodiment, the showerhead may be a 6061 aluminum alloy having a reduced zinc content. The reduced 6061 aluminum alloy may have a zinc content of less than or equal to 0.01 wt %. It is believed that when the chamber 100 is operated at temperatures above about 400° C. for extended periods of time, such as in an LTPS process, zinc present in the 6061 aluminum alloy may volatilize and deposit on surfaces in the chamber 100. The relatively high vapor pressure of zinc, in combination with temperature and pressure conditions of the chamber 100 during processing, may cause the volatilization which may ultimately result in zinc particles present in the chamber 100. It has been found that a 6061 aluminum alloy having less than or equal to 0.01 wt % zinc reduces or eliminates the creation of zinc particles within the chamber 100.

A gas source 132 can be coupled to the backing plate 112 to provide process gases through gas passages in the showerhead 106 to process volume 105 between the showerhead 106 and the substrate 120. The gas source 132 can include a silicon-containing gas supply source, an oxygen containing gas supply source, and a nitrogen-containing gas supply source, among others. Typical process gases useable with one or more embodiments include silane (SiH₄), disilane, N₂O, ammonia (NH₃), H₂, N₂ or combinations thereof.

A vacuum pump 110 may be coupled to the chamber 100 to control the process volume 105 at a desired pressure. An RF source 128 can be coupled through a match network 150 to the backing plate 112 and/or to the showerhead 106 to provide an RF current to the showerhead 106. The RF current creates an electric field between the showerhead 106 and the substrate support 118 so that a plasma may be generated from the gases between the showerhead 106 and the substrate support 118.

A remote plasma source 130, such as an inductively coupled remote plasma source 130, may also be coupled between the gas source 132 and the backing plate 112. Between processing substrates, a cleaning gas may be provided to the remote plasma source 130 so that a remote plasma is generated. The radicals from the remote plasma may be provided to chamber 100 to clean chamber 100 components. The cleaning gas may be further excited by the RF source 128 provided to the showerhead 106.

The showerhead 106 may additionally be coupled to the backing plate 112 by showerhead suspension 134. In one embodiment, the showerhead suspension 134 is a flexible metal skirt. The showerhead suspension 134 may have a lip 136 upon which the showerhead 106 may rest. The backing plate 112 may rest on an upper surface of a ledge 114 coupled with the chamber walls 102 to seal the chamber 100.

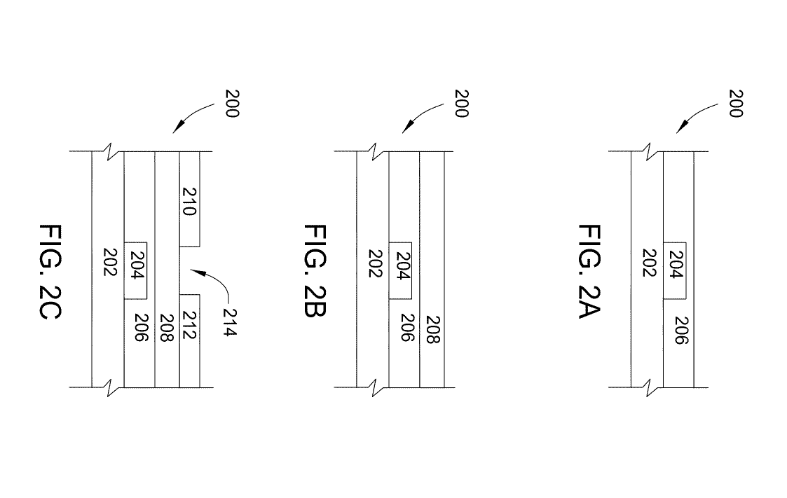

FIGS. 2A-2C are schematic cross-sectional views of a TFT 200 at various stages of production. As shown in FIG. 2A, a gate electrode 204 is formed over a substrate 202. Suitable materials that may be utilized for the substrate 202 include, but not limited to, silicon, germanium, silicon-germanium, soda lime glass, glass, semiconductor, plastic, steel or stainless steel substrates. Suitable materials that may be utilized for the gate electrode 204 include, but are not limited to, chromium, copper, aluminum, tantalum, titanium, molybdenum, and combinations thereof, or transparent conductive oxides (TCO) such as indium tin oxide (ITO) or fluorine doped zinc oxide (ZnO:F) which are commonly used as transparent electrodes. The gate electrode 204 may be deposited by suitable deposition techniques such as PVD, MOCVD, a spin-on process and printing processes. The gate electrode 204 may be patterned using an etching process.

Over the gate electrode 204, a gate dielectric layer 206 may be deposited. Suitable materials that may be used for the gate dielectric layer 206 include silicon dioxide, silicon oxynitride, silicon nitride, aluminum oxide or combinations thereof. The gate dielectric layer 206 may be deposited by suitable deposition techniques including plasma enhanced chemical vapor deposition (PECVD).

A semiconductor layer 208 is then formed over the gate dielectric layer 206 as shown in FIG. 2B. The semiconductor layer 208 comprises LTPS. In practice, the semiconductor layer 208 is oftentimes referred to as the channel layer, the active layer, or the semiconductor active layer.

As shown in FIG. 2C, over the semiconductor layer 208, the source electrode 210 and the drain electrode 212 are formed. The exposed portion of the semiconductor layer 208 between the source and drain electrodes 210, 212 is referred to as the slot or trench 214. Suitable materials for the source and drain electrodes 210, 212 include chromium, copper, aluminum, tantalum, titanium, molybdenum, and combinations thereof, or TCOs mentioned above. The source and drain electrodes 210, 212 may be formed by suitable deposition techniques, such as PVD followed by patterning through etching.

A TFT 200 formed in the chamber 100 may be adapted to control LCD or OLED displays. Thus, the TFT 200 may have a polysilicon semiconductor layer 208. The polysilicon semiconductor layer may comprise amorphous silicon or microcrystalline silicon which may be annealed into polysilicon. The annealing process may be performed at temperatures greater than about 400° C. As previously described, a showerhead 106 comprising a 6061 aluminum alloy may contain impurities, such as zinc, which may volatilize out of the showerhead 106 and deposit on surfaces within the chamber 100 when the showerhead 106 is subjected to elevated temperatures. The volatilized zinc may be in the form of a zinc powder which may deposit on various surfaces of the chamber 100. The zinc powder or particles may also deposit on the polysilicon semiconductor layer 208 during TFT 200 fabrication. The particles of zinc may degrade the TFT 200 performance. As such, utilizing a reduced zinc showerhead 106 may reduce or eliminate zinc particles within the chamber 100 when forming an LTPS TFT 200.

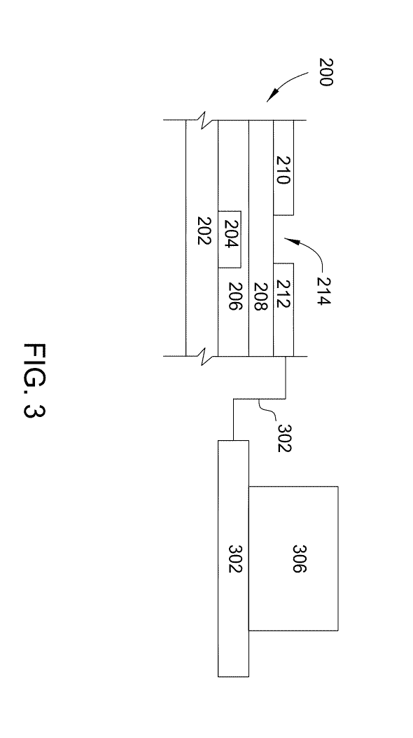

FIG. 3 is a cross-sectional schematic diagram of a TFT controlling an LCD pixel or OLED. The TFT 200 may be adapted to control a display pixel 306, such as an LCD or OLED display pixel. The display pixel 306 may be electrically coupled to the display pixel electrode 302 which may be electrically coupled via a connector 304 to the drain 212. The TFT 200 may provide an electrical signal via the connector 304 to the display pixel electrode 302 which may influence the display pixel 306. The performance of the TFT 200 is important in controlling the display pixel 306 and any particles present in the chamber 100 during formation of the TFT 200 may degrade performance. This is especially important when using polysilicon as the semiconductor layer 208 because of the elevated temperatures needed to form the polysilicon as the elevated temperatures in the chamber 100 may cause impurities in the showerhead 106 to volatilize out of the showerhead 106. The reduced zinc showerhead 106 as described above may reduce or eliminate the volatilization of zinc from the showerhead 106 and provide for a TFT with an uncontaminated polysilicon semiconductor layer 208.

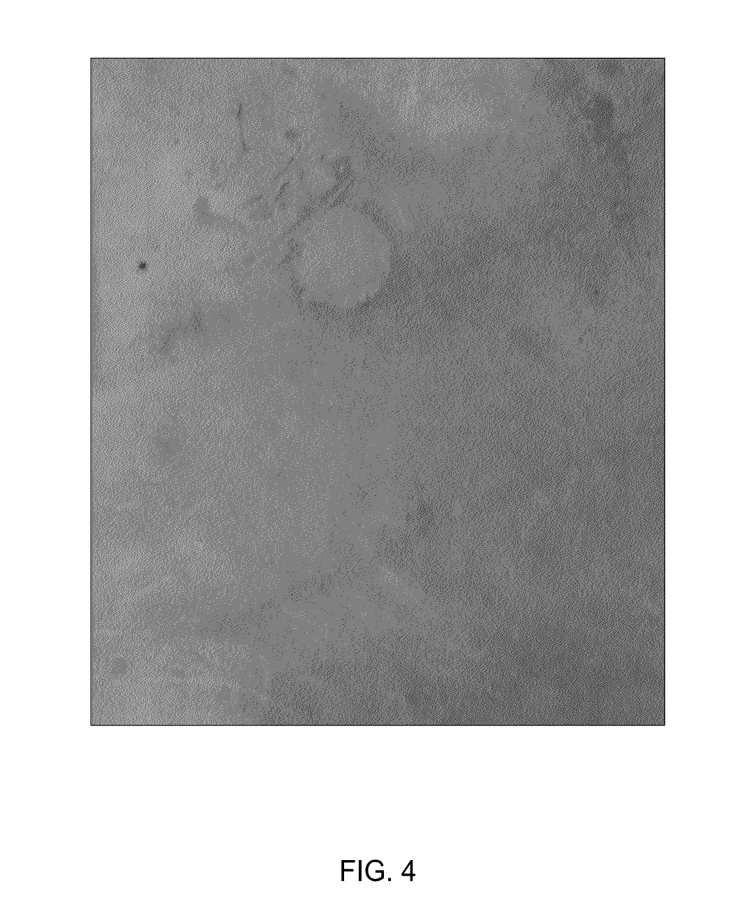

FIG. 4 is a color photograph of a portion of a backing plate having a zinc material deposited thereon. As shown, a bluish gray material is present on the backing plate. The bluish gray material is believed to be zinc particles which have volatilized and deposited on the backing plate after the chamber is operated at temperatures above about 400° C. for extended periods of time. In addition to depositing on the backing plate, the zinc material is also deposited on other chamber components, such as the walls of the chamber. It is believed that the bluish gray zinc material shown in FIG. 4 volatilized from a diffuser made of 6061 alloy aluminum having a zinc content greater than 0.01 wt %.

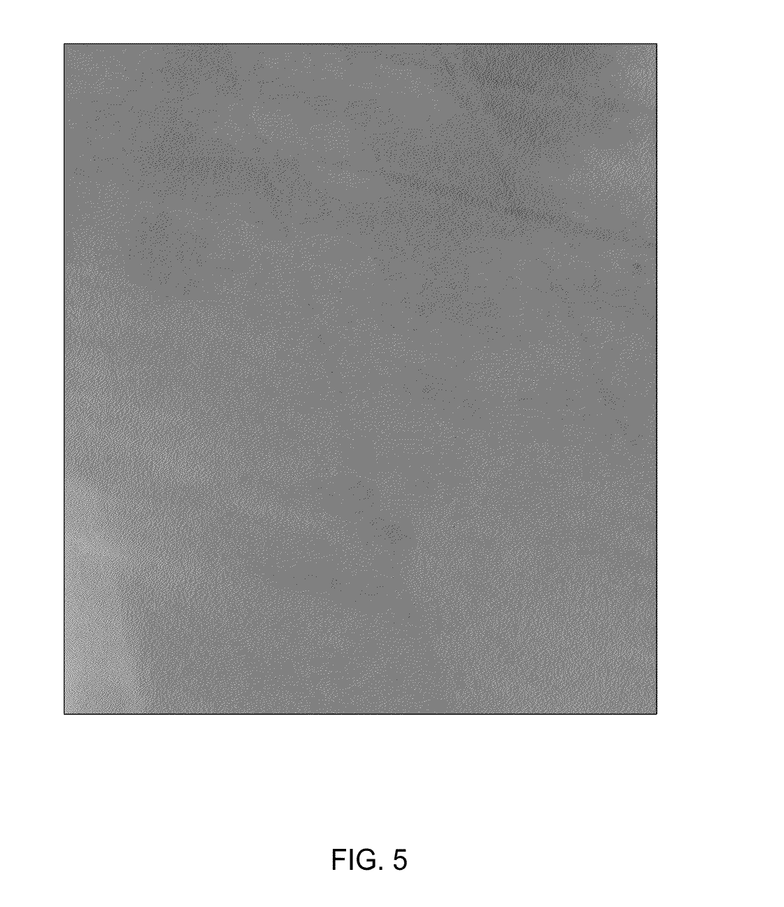

FIG. 5 is a color photograph of a portion of a backing plate having substantially no zinc material deposited thereon. As shown, substantially no bluish gray material is present on the backing plate when compared to the photograph of FIG. 4. FIG. 5 shows the backing plate after the chamber is operated at temperatures above about 400° C. for extended periods of time with a diffuser made from 6061 alloy aluminum wherein the zinc content of the alloy is less than or equal to 0.01 wt %. It is believed that utilizing a diffuser having a zinc content less than or equal to 0.01 wt % substantially reduces or eliminates the potential for zinc volatilization and deposition on the backing plate and other chamber components.

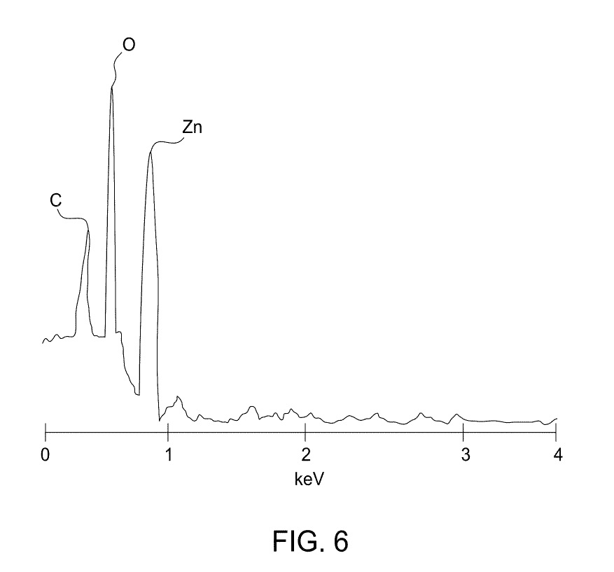

FIG. 6 is a graph illustrating elemental analysis of a portion of a chamber having a zinc material deposited thereon. For example, the backing plate of FIG. 4 may be representative of the results obtained in the elemental analysis illustrated in FIG. 6. Energy-dispersive X-ray spectroscopy was performed on a chamber component operated at temperatures above about 400° C. for extended periods of time at a pressure of about 2 Torr with a diffuser made from 6061 alloy aluminum wherein the zinc content of the alloy is greater to 0.01 wt %. The resulting elemental analysis of the chamber component with the bluish gray zinc material present proved the existence of carbon, oxygen, and zinc. Table 1 provides numerical representations of the amounts of the elements present from the graph of FIG. 6.

TABLE 1

| Element | Weight % | Atomic % |
|---|---|---|
| C | 10.63 | 23.35 |
| O | 32.61 | 53.76 |
| Zn | 56.75 | 22.89 |

While the foregoing is directed to embodiments of the present invention, other and further embodiments of the invention may be devised without departing from the basic scope thereof, and the scope thereof is determined by the claims that follow.

1. A diffuser for processing substrates, comprising:
a body comprising an aluminum alloy, wherein the aluminum alloy comprises less than or equal to 0.01 wt % of zinc.

2. The diffuser of claim 1, wherein the body has a plurality of passages disposed therethrough.

3. A diffuser for use in a plasma enhanced chemical vapor deposition chamber, comprising:
a body comprising an aluminum alloy containing less than or equal to 0.01 wt % of zinc, wherein the diffuser is adapted for operation in an environment having a temperature above 400° C.

4. The diffuser of claim 3, wherein the body has a plurality of passages disposed therethrough.

5. A PECVD apparatus, comprising:
diffuser for processing substrates, the diffuser comprising: a body comprising an aluminum alloy, wherein the aluminum alloy comprises less than or equal to 0.01 wt % of zinc.

6. The apparatus of claim 5, wherein the body is coupled to a backing plate by one or more fastening mechanisms and a showerhead suspension mechanism.

7. The apparatus of claim 6, wherein a gas source is coupled to the backing plate.

8. The apparatus of claim 6, wherein the body is disposed in a processing volume opposite a substrate support.

9. The apparatus of claim 5, wherein the body is coupled to an RF power source.

10. The apparatus of claim 5, wherein the aluminum alloy is substantially non-volatile at temperatures greater than about 400° C.
